(19) United States
(12) Patent Application Publication
(10) Pub. No.: US 2025/0125130 A1
(43) Pub. Date: Apr. 17, 2025

(54) CONTROL METHOD OF SUBSTRATE PROCESSING APPARATUS INCLUDING PARTIALLY ETCHING A WORKPIECE TO FROM A RECESS IN THE WORKPIECE AND SUBSTRATE PROCESSING SYSTEM

(71) Applicant: Tokyo Electron Limited, Tokyo (JP)

(72) Inventor: Sho KUMAKURA, Miyagi (JP)

(73) Assignee: Tokyo Electron Limited, Tokyo (JP)

(21) Appl. No.: 19/002,147

(22) Filed: Dec. 26, 2024

Related U.S. Application Data
(63) Continuation of application No. PCT/JP2023/023911, filed on Jun. 28, 2023.

(30) Foreign Application Priority Data
Jul. 1, 2022 (JP) 2022-107141

(51) Int. Cl. H01J 37/32; C23C 16/455; C23C 16/52; H01L 21/3065

(52) U.S. Cl. CPC H01J 37/32926; C23C 16/45536; C23C 16/45553; C23C 16/52; H01J 37/32091; H01J 37/32935; H01J 2237/3321; H01J 2237/334; H01L 21/3065

(57) ABSTRACT

A control method of a substrate processing apparatus and a substrate processing system. The control method includes: a step a) of partially etching a workpiece to form a recess in the workpiece; a step b) of forming a protective layer on a sidewall of the recess formed in the workpiece; a step c) of further etching the workpiece where the recess and the protective layer are formed; a step d) of repeating the steps b) and c); a step e) of monitoring the obtained workpiece; a step f) of executing a virtual experiment that simulates the steps a) to d); a step g) of deriving a parameter to be applied to at least one of the steps a) to d) based on a monitoring result of the workpiece and a result of the virtual experiment; and a step h) of executing at least one of the steps a) to e).

### CROSS-REFERENCE TO RELATED APPLICATIONS

This application is a bypass continuation application of international application No. PCT/JP2023/023911 having an international filing date of Jun. 28, 2023 and designating the United States, the international application being based upon and claiming the benefit of priority from Japanese Patent Application No. 2022-107141, filed on Jul. 1, 2022, the entire contents of each are incorporated herein by reference.

### TECHNICAL FIELD

The present disclosure relates to a control method of a substrate processing apparatus and a substrate processing system.

### BACKGROUND

As integration of semiconductor devices progresses not only in a horizontal direction but also in a vertical direction, an aspect ratio of a pattern formed in a process of manufacturing a semiconductor device also increases. For example, in 3D NAND manufacturing, channel holes are formed in a direction that penetrates many metal wiring layers. When 64 layers of memory cells are formed, an aspect ratio of the channel holes may become as high as 45.

To precisely form a pattern with a high aspect ratio, various methods are proposed. For example, by repeatedly executing etching and layer formation on an opening formed on a dielectric material of a substrate, a method of suppressing etching in a lateral direction is proposed. In addition, a method of combining etching and layer formation to form a protective layer for preventing etching in a lateral direction of a dielectric layer is proposed (for example, refer to Patent Document 1).

### CITATION LIST

### Patent Documents

Patent Document 1: US2018/0247798A

### SUMMARY

The present disclosure provides a control method of a substrate processing apparatus and a substrate processing system in which a satisfactory opening shape can be efficiently guided.

According to one embodiment of the present disclosure, a control method of a substrate processing apparatus includes: a step a) of partially etching a workpiece to form a recess in the workpiece; a step b) of forming a protective layer on a sidewall of the recess formed in the workpiece; a step c) of further etching the workpiece where the recess and the protective layer are formed; a step d) of repeating the steps b) and c); a step e) of monitoring the workpiece obtained in at least one of the steps a) to d); a step f) of executing a virtual experiment that simulates the steps a) to d); a step g) of deriving a parameter to be applied to at least one of the steps a) to d) based on a monitoring result of the workpiece and a result of the virtual experiment; and a step h) of executing at least one of the steps a) to d) to which the derived parameter is applied.

According to the present disclosure, a satisfactory opening shape can be efficiently guided.

### BRIEF DESCRIPTION OF THE DRAWINGS

FIG. 1 is a diagram illustrating a configuration example of a substrate processing system.

FIG. 2 is a diagram illustrating a configuration example of a capacitively coupled plasma processing apparatus.

FIG. 3 is a flowchart illustrating the flow of general ALD.

FIGS. 4A to 4D are diagrams illustrating a first method of sub-conformal ALD.

FIGS. 5A to 5C are diagrams illustrating a second method of sub-conformal ALD.

FIG. 6 is a flowchart illustrating the flow of ALD according to the present embodiment.

FIG. 7 is a flowchart illustrating the flow of ALD according to the present embodiment.

FIG. 8 is a diagram illustrating a configuration example of an etching simulator.

FIG. 9 is a flowchart illustrating a model update procedure.

FIGS. 10A and 10B are diagrams illustrating a layer thickness of a protective layer formed using a substrate processing method according to an embodiment.

FIG. 11 is a schematic diagram illustrating a reinforcement learning algorithm.

FIG. 12 is a schematic diagram illustrating a first configuration example of a plasma processing system according to a third embodiment.

FIG. 13 is a schematic diagram illustrating a second configuration example of the plasma processing system according to the third embodiment.

### DETAILED DESCRIPTION

Hereinafter, the present disclosure will be described in detail based on the drawings illustrating embodiments of the present disclosure.

### First Embodiment

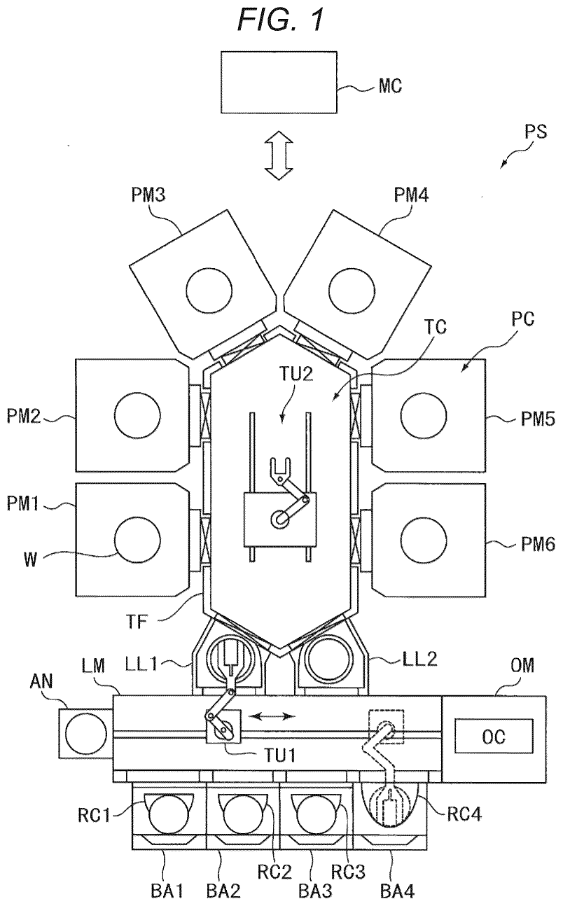

FIG. 1 is a diagram illustrating a configuration example of a substrate processing system. A substrate processing system PS includes tables BA1 to BA4, containers RC1 to RC4, a loader module LM, an aligner AN, load lock modules LL1 and LL2, process modules PM1 to PM6, a transfer module TF, and a control apparatus MC. Each of the number of the tables, the number of the containers, and the number of the load lock modules in the substrate processing system PS may be any number of one or more. The number of the process modules in the substrate processing system PS may be any number of two or more.

The tables BA1 to BA4 are arranged along one edge of the loader module LM. The containers RC1 to RC4 are mounted on the tables BAI to BA4, respectively. Each of the containers RC1 to RC4 is called, for example, a front opening unified pod (FOUP). Each of the containers RC1 to RC4 is configured to accommodate a substrate W.

The loader module LM includes a chamber. A pressure in the chamber of the loader module LM is set to atmospheric pressure. The loader module LM includes a transfer apparatus TU1. The transfer apparatus TU1 is, for example, an articulated robot, and is controlled by the control apparatus MC. The transfer apparatus TU1 is configured to transfer the substrate W via the chamber of the loader module LM. The transfer apparatus TU1 can transfer the substrate W between each of the containers RC1 to RC4 and the aligner AN, between the aligner AN and each of the load lock modules LL1 and LL2, and between each of the load lock modules LL1 and LL2 and each of the containers RC1 to RC4. The aligner AN is connected to the loader module LM. The aligner AN is configured to adjust (calibrate) a position of the substrate W.

Each of the load lock module LL1 and the load lock module LL2 is provided between the loader module LM and the transfer module TF. Each of the load lock module LL1 and the load lock module LL2 provides a preliminary decompression chamber.

The transfer module TF is connected to each of the load lock module LL1 and the load lock module LL2 via a gate valve. The transfer module TF includes a transfer chamber TC that can be decompressed. The transfer module TF includes a transfer apparatus TU2. The transfer apparatus TU2 is, for example, an articulated robot, and is controlled by the control apparatus MC. The transfer apparatus TU2 is configured to transfer the substrate W via the transfer chamber TC. The transfer apparatus TU2 can transfer the substrate W between each of the load lock modules LL1 and LL2 and each of the process modules PMI to PM6 and between any two process modules among the process modules PMI to PM6.

Each of the process modules PM1 to PM6 is a processing apparatus configured to execute a dedicated substrate process. One process module among the process modules PMI to PM6 is a layer forming apparatus. The layer forming apparatus is used for forming a protective layer PF in a layer formation process described below. The layer forming apparatus is a plasma processing apparatus having a configuration for generating plasma when plasma is generated in the layer formation process, and may not have a configuration for generating plasma when the protective layer PF is formed without generating plasma in the layer formation process. Another process module among the process modules PMI to PM6 is an etching apparatus. The etching apparatus is used for forming a pattern on a surface of a workpiece in an etching process described below.

In the substrate processing system PS, the control apparatus MC is configured to control each of the units in the substrate processing system PS. The control apparatus MC can control, for example, an operation of the etching apparatus to form a recess in the workpiece and form a pattern on a surface of the workpiece. The control apparatus MC can control the layer forming apparatus to form a protective layer on a sidewall of the formed recess.

The substrate processing system PS includes an observation apparatus OC. The observation apparatus OC can be provided in any location in the substrate processing system PS. For example, the observation apparatus OC is provided in an observation module OM adjacent to the loader module LM. The substrate W can be moved between the observation module OM and the process modules PM1 to PM6 by the transfer apparatus TU1 and the transfer apparatus TU2. The substrate W is accommodated in the observation module OM by the transfer apparatus TU1. The substrate W is aligned in the observation module OM, and then the observation apparatus OC measures a groove width of a pattern such as a mask of the substrate W, and transmits a measurement result to the control apparatus MC. The observation apparatus OC can measure the groove width of a pattern such as masks formed in a plurality of regions of the substrate W surface. As the observation apparatus OC, for example, an optical observation apparatus, a gravimeter, or an ultrasonic microscope can be used.

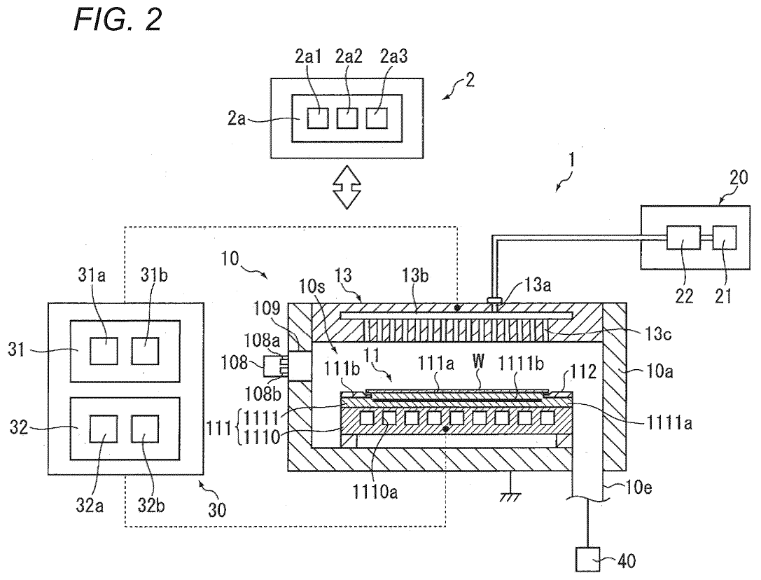

Hereinafter, a configuration example of a plasma processing system will be described. FIG. 2 is a diagram illustrating a configuration example of a capacitively coupled plasma processing apparatus.

The plasma processing system includes a capacitively coupled plasma processing apparatus 1 and a controller 2. The controller 2 includes circuitry such as a central processing unit (CPU) and a memory such as a read only memory (ROM) and/or a random access memory (RAM). The capacitively coupled plasma processing apparatus 1 includes a plasma processing chamber 10, a gas supply 20, a power source 30, and an exhaust system 40. The plasma processing apparatus 1 also includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In an exemplary embodiment, the shower head 13 is configured to be at least a part of a ceiling of the plasma processing chamber 10. The plasma processing chamber 10 includes a plasma processing space 10s defined by the shower head 13, a sidewall 10a of the plasma processing chamber 10, and the substrate support 11. The plasma processing chamber 10 includes at least one gas supply port for supplying at least one processing gas to the plasma processing space 10s and at least one gas exhaust port for exhausting gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 includes a central region 111a for supporting the substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a includes the central region 111a. In one embodiment, the ceramic member 1111a also includes the annular region 111b. Other members/structures that surround the electrostatic chuck 1111, such as an annular electrostatic chuck and an annular insulating member, may include the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled with a radio frequency (RF) power source 31 and/or a direct current (DC) power source 32 may be disposed in the ceramic member 1111a. In this case, at least one RF/DC electrode functions as a lower electrode. When a bias RF signal and/or DC signal described below is supplied to at least one RF/DC electrode, the RF/DC electrode is also called a bias electrode. The conductive member of the base 1110 and at least one RF/DC electrode may function as a plurality of lower electrodes. The electrostatic electrode 1111b may also function as a lower electrode. Accordingly, the substrate support 11 includes at least one lower electrode.

The ring assembly 112 includes one or a plurality of annular members. In one embodiment, the one or a plurality of annular members include one or a plurality of edge rings and at least one cover ring. The edge ring is formed of a conductive material or an insulating material, and the cover ring is formed of an insulating material.

In addition, the substrate support 11 may include a temperature control module that is configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or a plurality of heaters are disposed in the ceramic member 1111a of the electrostatic chuck 1111. In addition, the substrate support 11 may include a heat transfer gas supply configured to supply heat transfer gas to a gap between a rear surface of the substrate W and the central region 111a.

The shower head 13 is configured to introduce at least one processing gas from the gas supply 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b, and is introduced from the plurality of gas introduction ports 13c into the plasma processing space 10s. In addition, the shower head 13 includes at least one upper electrode. The gas introduction unit may include, in addition to the shower head 13, one or a plurality of side gas injectors (SGI) attached to one or a plurality of openings formed in the sidewall 10a.

The gas supply 20 may include at least one gas source 21 and at least one flow rate controller 22. In one embodiment, the gas supply 20 is configured to supply at least one processing gas from the corresponding gas source 21 to the shower head 13 via the corresponding flow rate controller 22. Each of the flow rate controllers 22 may include, for example, a mass flow controller or a pressure-controlled flow rate controller. Further, the gas supply 20 may include one or a plurality of flow rate modulation devices that modulates or pulses the flow rate of at least one processing gas.

The power source 30 includes the RF power source 31 coupled with the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied to the plasma processing space 10s. Accordingly, the RF power source 31 can function as at least a part of a plasma generator configured to generate plasma from one or a plurality of processing gas in the plasma processing chamber 10. In addition, by supplying the bias RF signal to at least one lower electrode, a bias potential is generated in the substrate W, and an ionic component in the formed plasma can be attracted to the substrate W.

In an exemplary embodiment, the RF power source 31 includes a first RF generator 31a and a second RF generator 31b. The first RF generator 31a is coupled with at least one lower electrode and/or at least one upper electrode via at least one impedance matching circuit, and is configured to generate a source RF signal (source RF power) for generating plasma. In one embodiment, the source RF signal has a frequency in a range of 10 MHz to 150 MHz. In an exemplary embodiment, the first RF generator 31a may be configured to generate a plurality of source RF signals having different frequencies. The one or a plurality of generated source RF signals are supplied to at least one lower electrode and/or at least one upper electrode.

The second RF generator 31b is coupled with at least one lower electrode via at least one impedance matching circuit, and is configured to generate the bias RF signal (bias RF power). The frequency of the bias RF signal may be the same as or different from the frequency of the source RF signal. In an exemplary embodiment, the bias RF signal has a frequency lower than the frequency of the source RF signal. In an exemplary embodiment, the bias RF signal has a frequency in a range of 100 kHz to 60 MHz. In an exemplary embodiment, the second RF generator 31b may be configured to generate a plurality of bias RF signals having different frequencies. The one or a plurality of generated bias RF signals are supplied to at least one lower electrode. In various embodiments, at least one of the source RF signal and the bias RF signal may be pulsed.

In addition, the power source 30 includes the DC power source 32 coupled with the plasma processing chamber 10. The DC power source 32 includes a first DC generator 32a and a second DC generator 32b. In an exemplary embodiment, the first DC generator 32a is connected to at least one lower electrode, and is configured to generate a first DC signal. The generated first DC signal is applied to at least one lower electrode. In an exemplary embodiment, the second DC generator 32b is connected to at least one upper electrode, and is configured to generate a second DC signal. The generated second DC signal is applied to at least one upper electrode.

In various embodiments, at least one of the first and second DC signals may be pulsed. In this case, a sequence of pulse voltages is applied to at least one lower electrode and/or at least one upper electrode. The pulse voltage may have a pulse waveform of a rectangular shape, a trapezoidal shape, a triangular shape, or a combination thereof. In one embodiment, a waveform generator for generating a sequence of pulse voltages from the DC signal is connected between the first DC generator 32a and at least one lower electrode. Accordingly, the first DC generator 32a and the waveform generator configure a pulse voltage generator. When the second DC generator 32b and the waveform generator configure the pulse voltage generator, the pulse voltage generator is connected to at least one upper electrode. The pulse voltage may have positive polarity or negative polarity. The sequence of pulse voltages may include one or a plurality of positive pulse voltages and one or a plurality of negative pulse voltages in one cycle. The first and second DC generators 32a and 32b may be provided in addition to the RF power source 31, or the first DC generator 32a may be provided instead of the second RF generator 31b.

The exhaust system 40 can be connected to, for example, a gas exhaust port 10e provided in a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbomolecular pump, a dry pump, or a combination thereof.

An optical sensor 108 that can measure an intensity of light of each wavelength in plasma in the plasma processing space 10s via a quartz window 109 is attached to the plasma processing apparatus 1. The optical sensor 108 includes a first sensor 108a and a second sensor 108b. The first sensor 108a is a sensor for sensing a state of plasma generated in the plasma processing space 10s. The second sensor 108b is a sensor for sensing a pattern shape of the substrate W surface placed on the base 1110. Sensing data of the first sensor 108a and the second sensor 108b are output to the controller 2. The controller 2 measures/estimates the plasma state in the plasma processing chamber 10 and the pattern shape of the substrate W based on the sensing data of the first sensor 108a and the second sensor 108b.

The controller 2 processes computer-executable instructions that cause the plasma processing apparatus 1 to execute various steps described in the present disclosure. The controller 2 may be configured to control each component of the plasma processing apparatus 1 to execute various steps described herein. In an exemplary embodiment, a part or all of the controller 2 may be included in the plasma processing apparatus 1. The controller 2 may include a processing unit 2a1, a storage unit 2a2, and a communication interface 2a3. The controller 2 is implemented by, for example, a computer 2a. The processing unit 2a1 may be configured to execute various control operations by reading a program from the storage unit 2a2 and executing the read program. The program may be stored in the storage unit 2a2 in advance or may be acquired via a medium when necessary. The acquired program is stored in the storage unit 2a2, and is read from the storage unit 2a2 and executed by the processing unit 2a1. The medium may be various storage media that are readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a LAN.

The program stored in the storage unit 2a2 includes a simulator for virtual experiment that simulates a process executed in the substrate processing system PS (actual experiment). The simulator for virtual experiment includes a plasma simulator, a reaction product simulator, and a shape simulator. The program stored in the storage unit 2a2 may be a program for implementing a virtual metrology (VM) technique. The computer program may be a single computer program or may be configured with a plurality of computer programs. An existing library may be partially used as the computer program.

Hereinafter, a process executed in the substrate processing system PS will be described. When a pattern such as a high aspect ratio contact (HARC) is formed on a substrate that is a workpiece, shape deformation called bowing may occur. Bowing is a phenomenon in which, even when an opening is formed in a longitudinal direction (thickness direction of the substrate), an inner peripheral surface of the opening expands in a lateral direction (in-plane direction of the substrate). To prevent occurrence of the shape deformation, a method of forming a protective layer on a sidewall of the opening is proposed. As a layer forming method for such a protective layer, for example, atomic layer deposition (ALD) is used. In the present exemplary embodiment, a layer formation process using ALD will mainly be described. Alternatively, other layer forming methods such as plasma-enhanced ALD (PEALD), chemical vapor deposition (CVD), plasma-enhanced CVD (PECVD), and plasma-enhanced cyclic chemical vapor deposition (PECCVD) can be used.

In the following description, “pattern” refers to an overall shape formed on the substrate. The pattern refers to, for example, all of a plurality of shapes formed on the substrate, such as a hole, a trench, or a line-and-space pattern. In addition, “recess” refers to a portion in the pattern formed on the substrate having a concave shape in the thickness direction of the substrate. In addition, the recess includes “sidewall” that is an inner peripheral surface of the concave shape, “bottom portion” that is a bottom portion of the concave shape, and “top portion” that is a substrate surface continuous to the sidewall in the vicinity of the sidewall. In addition, a space surrounded by the top portion is called “opening”. The term “opening” may be used to represent an entire space surrounded by the bottom portion and the sidewall of the recess or any position of the space.

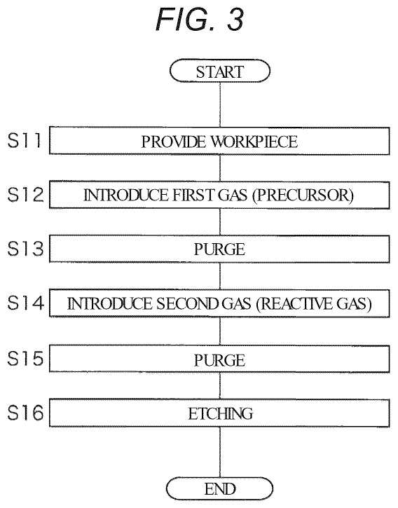

FIG. 3 is a flowchart illustrating the flow of general ALD. The substrate processing system PS provides a workpiece into the plasma processing chamber 10 (Step S11). The workpiece is, for example, a substrate on which a pattern having a high aspect ratio is formed by another process module. Alternatively, the workpiece may be a substrate on which a pattern is not formed. In this case, in the plasma processing apparatus 1, the workpiece may be partially etched to form a pattern.

The plasma processing apparatus 1 introduces first gas into the plasma processing chamber 10 (Step S12). The first gas is also called a precursor. The plasma processing apparatus 1 purges the plasma processing chamber 10 to exhaust components of the first gas excessively adsorbed on the surface of the workpiece (Step S13).

The plasma processing apparatus 1 introduces second gas into the plasma processing chamber 10 and generates plasma of the second gas (Step S14). The second gas is also called reactive gas. The plasma processing apparatus 1 purges the plasma processing chamber 10 to exhaust excessive components of the second gas (Step S15).

A protective layer is formed on the sidewall of the opening by the process of Steps S12 to S15. After forming the protective layer, the plasma processing apparatus 1 etches the workpiece (Step S16).

The flowchart of FIG. 3 illustrates a procedure in which both of the layer formation process and the etching process are executed in one plasma processing apparatus 1. However, the layer formation process may be executed in one plasma processing apparatus, and the etching process may be executed in another plasma processing apparatus. In addition, the layer formation process and the etching process may be executed in the same substrate processing system or may be executed in different substrate processing systems.

In addition, the plasma processing apparatus 1 may measure a layer thickness of the protective layer after Step S15 to determine whether a required layer thickness is obtained. When the required layer thickness is not obtained, the plasma processing apparatus 1 may return the process to Step S12 to continue formation of the protective layer. To measure the layer thickness, the second sensor 108b is used in in-situ measurement, and the observation apparatus OC is used in ex-situ measurement.

The plasma processing apparatus 1 may measure the shape of the pattern after Step S16 to determine whether a required shape is obtained. When a required shape is not obtained, the plasma processing apparatus 1 may return the process to Step S12 to continue formation of the protective layer and etching. To measure the shape, the second sensor 108b is used in in-situ measurement, and the observation apparatus OC is used in ex-situ measurement.

In ALD, a specific component is adsorbed on a material on the substrate surface in a self-limiting manner and reacts with the material to form a layer. Therefore, in ALD, by providing a sufficient processing time, conformal layer formation can be implemented. For example, in the flowchart of FIG. 3, when processing times of Steps S12 and S14 are sufficiently long (when a processing condition is set to a saturation condition), adsorption of the components of the first gas on the substrate and reaction between the components of the first gas and the components of the second gas are saturated, and a conformal layer is formed. The conformal layer refers to a layer having a uniform thickness regardless of the position on the substrate (for example, the position in the vertical direction).

On the other hand, in sub-conformal ALD, while using the same procedure as that of ALD, the process condition is controlled such that at least one of adsorption and reaction of layer forming components is not saturated. That is, in sub-conformal ALD, a sub-conformal layer is formed by not allowing completion of self-limiting adsorption or reaction on the surface of the substrate. The sub-conformal layer is a layer where the layer thickness changes depending on the position on the substrate (for example, the position in the vertical direction). For example, the sub-conformal layer may be a layer where an upper side (opening side) is thick and a lower side is thin, or may be a layer where the layer thickness decreases from the upper side toward the lower side.

As process aspects of the sub-conformal ALD, at least two following aspects are used. (1) The precursor is adsorbed on the entire surface of the substrate. Reactive gas to be introduced subsequently is controlled not to spread over the entire surface of the substrate. (2) The precursor is adsorbed on only a part of the surface of the substrate. The reactive gas to be introduced subsequently is deposited on only a surface portion on which the precursor is adsorbed. By using the method (1) or (2), a layer of which the thickness gradually decreases from the upper side toward the lower side can be formed on the sidewall of the pattern formed on the substrate.

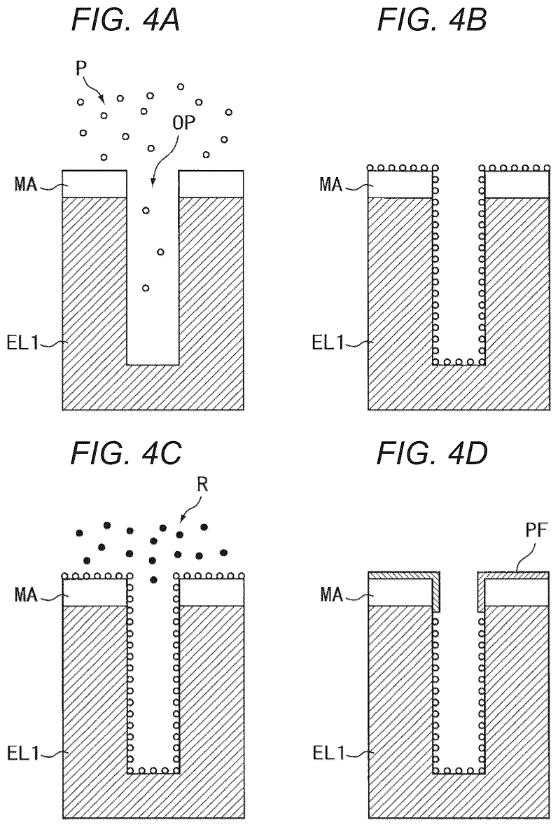

FIGS. 4A to 4D are diagrams illustrating a first method of the sub-conformal ALD. A workpiece illustrated in FIGS. 4A to 4D includes an etching target layer EL1 and a mask MA. In a stacked body of the etching target layer EL1 and the mask MA, a recess including an opening OP is formed.

The plasma processing apparatus 1 introduces a precursor P into the plasma processing chamber 10 where the workpiece is disposed (FIG. 4A). In the first method, a sufficient processing time for adsorption of the precursor P is set. As a result, the precursor P is adsorbed to the entire surface of the workpiece (FIG. 4B). After the adsorption of the precursor P ends, the plasma processing apparatus 1 purges the plasma processing chamber 10, and subsequently introduces reactive gas R into the plasma processing chamber 10 (FIG. 4C). The introduced reactive gas R reacts with the precursor P on the workpiece to gradually form the protective layer PF from above the mask MA. Here, the reactive gas R is purged before formation of the protective layer PF reaches a region below the etching target layer EL1. By the above-described process, while using the method of ALD, the protective layer PF can be formed on only upper portions of the mask MA and the etching target layer EL1 instead of forming the protective layer PF on the entire sidewall of the recess (FIG. 4D). In FIG. 4D, the protective layer PF is formed on the upper portion of the sidewall and the top portion of the recess, but is not formed on a lower portion of the sidewall and the bottom portion.

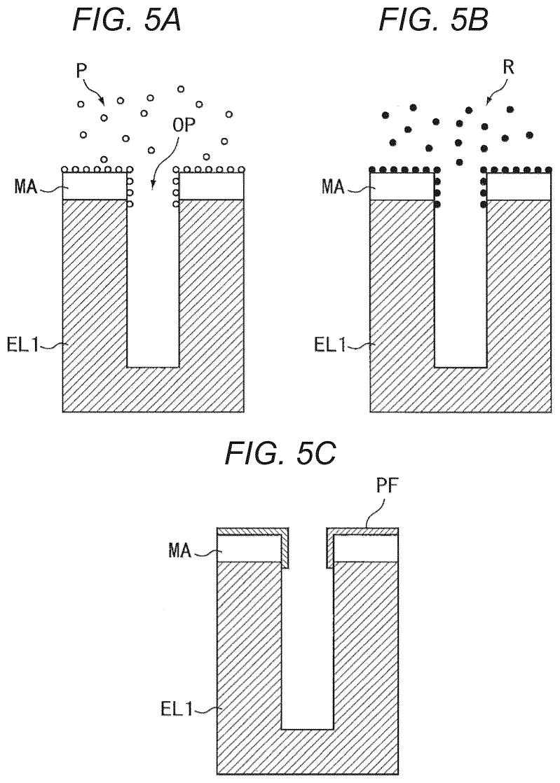

FIGS. 5A to 5C are diagrams illustrating a second method of the sub-conformal ALD. A shape of a workpiece illustrated in FIGS. 5A to 5C is the same as the shape of the workpiece illustrated in FIGS. 4A to 4D.

In the second method, the plasma processing apparatus 1 causes the precursor P to be adsorbed on only the upper portion of the workpiece (FIG. 5A). After purging the precursor P, the plasma processing apparatus 1 introduces the reactive gas R into the plasma processing chamber 10 (FIG. 5B). Here, the reactive gas R reacts and is deposited only on the position where the precursor P is adsorbed. Therefore, the protective layer PF is formed only on the upper portion of the workpiece (FIG. 5C).

FIGS. 4A to 4D correspond to an example where Step S14 of FIG. 3 is executed under an unsaturation condition, and FIGS. 5A to 5C correspond to an example where Step S12 of FIG. 3 is executed under an unsaturation condition. When processing times of Steps S12 and S14 are sufficiently long, a conformal layer is formed. Therefore, in sub-conformal ALD, the process condition is set such that at least one of adsorption and reaction of the layer forming components is not saturated.

The process conditions adjusted for implementing the sub-conformal ALD are, for example, a temperature of the substrate support 11 on which the substrate W is placed, a pressure in the plasma processing chamber 10, a flow rate and an introduction time of the precursor to be introduced, a gas flow rate and an introduction time of the reactive gas to be introduced, or a processing time. In a process where plasma is used, a layer formation position can also be adjusted by adjusting a value of radio frequency (RF) power to be applied for generating plasma. In the process of FIG. 3, the second gas in Step S14 is converted into plasma, and the first gas in Step S12 may also be converted into plasma.

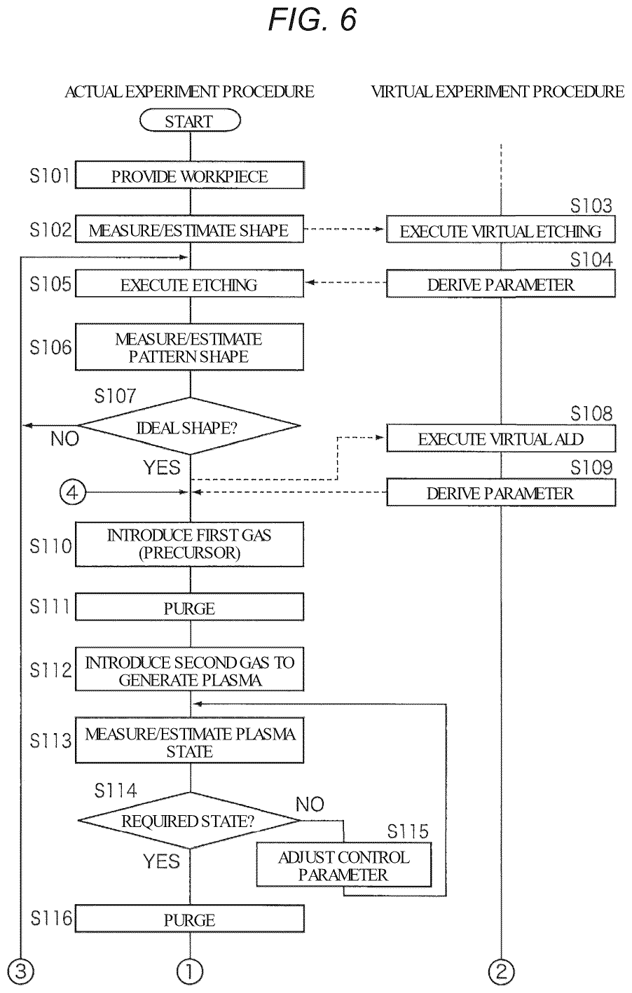

FIGS. 6 and 7 are flowcharts illustrating the flow of ALD according to the present embodiment. The substrate processing system PS provides a workpiece into the plasma processing chamber 10 (Step S101). The workpiece is a substrate on which a pattern is not formed. In the plasma processing apparatus 1, sensing by the second sensor 108b is executed frequently, and sensing data obtained by the second sensor 108b is output to the controller 2. The controller 2 measures/estimates a shape of the workpiece surface provided into the plasma processing chamber 10 based on the sensor data of the second sensor 108b (Step S102). The shape measured/estimated in Step S102 may be a shape of each of recesses formed on the surface of the workpiece or may be uniformity of an overall recess shape on the workpiece surface.

Not only the sensor data of the second sensor 108b but also information regarding the substrate to be processed, a process condition of the etching process, various types of output data output from the plasma processing apparatus 1, and various types of measurement data measured during execution of the etching process are input to the controller 2. Here, the information regarding the substrate to be processed includes information such as a material, a thickness, an aspect ratio, and a mask coverage of the substrate. The process conditions of the etching process include information such as a pressure in the chamber, a power of the radio frequency power source, a gas flow rate, a gas mixing ratio, a temperature in the chamber, and a temperature of the workpiece surface. The output data of the plasma processing apparatus 1 includes data such as source RF power, bias RF power, and a light emission intensity measured by an optical emission spectrometer (OES). The measurement data during execution of the process includes data such as a plasma density, ion energy, and an ion flow rate.

The controller 2 executes virtual etching that simulates the etching process in the plasma processing apparatus 1 (Step S103). The controller 2 estimates a shape of the workpiece after etching by simulation when the pattern shape measured/estimated in Step S102 is set as an initial shape. A configuration example of an etching simulator will be described below in detail.

The controller 2 acquires various parameters used in the virtual etching, and derives parameters to be applied to an actual experiment based on the acquired parameters (Step S104). Here, the parameters used in the virtual etching include not only the parameters of the substrate such as a material, a thickness, an aspect ratio, and a mask coverage of the substrate but also a pressure in the chamber, a power of the radio frequency power source, a gas flow rate, a gas mixing ratio, a temperature in the chamber, a temperature of the workpiece surface, source RF power, bias RF power, a light emission intensity measured by OES, a plasma density, an ion energy, and an ion flow rate. The type of the parameter to be applied to the actual experiment may be set in advance or may be selected by the controller 2. For example, the controller 2 may compare the parameter set by the actual experiment and the parameter acquired by the virtual experiment to each other to select the parameter to be applied to the actual experiment based on a difference between the parameters.

When deriving the parameter to be applied to the actual experiment in Step S104, the controller 2 may use a learning model of machine learning including deep learning or reinforcement learning, a statistical model, or a model including a combination thereof. The model is generated by acquiring a quantitative relationship that is satisfied between the parameter used in the virtual etching and the parameter to be applied to the actual experiment using a well-known method of machine learning, statistical analysis, or the like. The controller 2 can derive the parameters to be applied to the actual experiment by inputting the parameters acquired in Step S104 to the generated model.

The controller 2 may optimize the parameter to be applied to the actual experiment such that a concordance rate between the shape measured/estimated in the actual experiment and the shape predicted in the virtual experiment increases or the process processing time (throughput) is shortened.

The plasma processing apparatus 1 acquires the parameter derived by the virtual experiment of Step S103, and executes etching to which the acquired parameter is applied (Step S105). The etching process is a process in the actual experiment.

The controller 2 acquires sensing data output from the second sensor 108b during execution of etching (actual experiment). The controller 2 measures/estimates a pattern shape of a pattern formed by the etching in Step S105 based on the sensing data of the second sensor 108b (Step S106). The shape measured/estimated in Step S106 may be a shape of each of recesses formed on the surface of the workpiece or may be uniformity of an overall recess shape on the workpiece surface.

The controller 2 determines whether an ideal shape is obtained based on a measurement/estimation result of the pattern shape (Step S107). The controller 2 measures/estimates a shape of a recess formed by etching based on the sensor data obtained by the second sensor 108b, and determines whether the recess has a required aspect ratio to determine whether an ideal shape is obtained. Alternatively, the controller 2 may measure/estimate an opening width and an opening depth of the recess formed by etching, and may determine whether the opening width and the opening depth are in a set range to determine whether an ideal shape is obtained.

The controller 2 may compare the measurement/estimation result of the pattern shape and a set value set for the pattern shape to each other, and may stop the following process according to a comparison result. The set value is a value set for the aspect ratio, the opening width, the opening depth, or the like of the pattern shape. Alternatively, the controller 2 may output a warning according to the comparison result between the measurement/estimation result of the pattern shape and the set value. For example, the controller 2 outputs a warning by notifying information representing that the measurement/estimation result of the pattern shape exceeds the set value (or is less than the set value) to a terminal carried by a user via the communication interface 2a3. When the computer 2a includes a display or a sound output unit, the controller 2 may output a warning by causing the display to display text information or causing the sound output unit to output a sound.

When it is determined that an ideal shape is not obtained (S107: NO), the controller 2 returns the process to Step S105, and continues the etching on the workpiece until an ideal shape is obtained. Here, the controller 2 may frequently acquire various types of output data output from the plasma processing apparatus 1 or various types of measurement data during execution of etching, and may repeatedly execute the virtual etching with reference to the acquired data. The controller 2 can derive the parameter to be applied to the actual experiment from the virtual etching, and can apply the derived parameter to the etching repeatedly executed in the plasma processing apparatus 1 (actual experiment).

The controller 2 executes virtual ALD after executing the virtual etching in Step S103 (Step S108). The controller 2 estimates a shape of the workpiece after the ALD by simulation when the pattern shape obtained by the virtual etching in Step S103 is set as an initial shape. A configuration example of an ALD simulator will be described below in detail.

The controller 2 acquires various parameters used in the virtual ALD, and derives parameters to be applied to an actual experiment based on the acquired parameters (Step S109). The parameters used in the virtual ALD are the same as the parameters of the virtual etching, and include parameters such as a material, a thickness, an aspect ratio, and a mask coverage of the substrate, a pressure in the chamber, a power of the radio frequency power source, a gas flow rate, a gas mixing ratio, a temperature in the chamber, a temperature of the workpiece surface, source RF power, bias RF power, a light emission intensity measured by OES, a plasma density, an ion energy, and an ion flow rate. The type of the parameter to be applied to the actual experiment may be set in advance or may be selected by the controller 2. For example, the controller 2 may compare the parameter set by the actual experiment and the parameter acquired by the virtual experiment to each other to select the parameter to be applied to the actual experiment based on a difference between the parameters.

When deriving the parameter to be applied to the actual experiment in Step S109, the controller 2 may use a learning model of machine learning including deep learning or reinforcement learning, a statistical model, or a model including a combination thereof. The model is generated by acquiring a quantitative relationship that is satisfied between the parameter used in the virtual ALD and the parameter to be applied to the actual experiment using a well-known method of machine learning, statistical analysis, or the like. The controller 2 can derive the parameters to be applied to the actual experiment by inputting the parameters acquired in Step S109 to the generated model.

The controller 2 may optimize the parameter to be applied to the actual experiment such that a concordance rate between the shape measured/estimated in the actual experiment and the shape predicted in the virtual experiment increases or the process processing time (throughput) is shortened.

When an ideal shape is obtained in Step S107 (S107: YES), the plasma processing apparatus 1 acquires the parameter derived by the virtual ALD, and executes ALD to which the acquired parameter is applied. The ALD is a process in the actual experiment. The ALD to be executed may be conformal ALD or may be sub-conformal ALD. The ALD is executed through the following procedure of Steps S110 to S118.

The plasma processing apparatus 1 introduces first gas (precursor) into the plasma processing chamber 10 (Step S110). Next, the plasma processing apparatus 1 purges the plasma processing chamber 10 to exhaust components of the first gas excessively adsorbed on the surface of the workpiece (Step S111).

The plasma processing apparatus 1 introduces second gas (reactive gas) into the plasma processing chamber 10 and generates plasma of the second gas (Step S112).

The controller 2 acquires sensing data output from the first sensor 108a during the generation of plasma, and measures/estimates a plasma state based on the acquired sensing data (Step S113). The controller 2 determines whether the plasma state in the plasma processing chamber 10 is a required state based on a measurement/estimation result of the plasma state (Step S114). When it is determined that the plasma state is not the required state (S114: NO), the controller 2 adjusts the control parameters such as source RF power and bias RF power (Step S115), and returns the process to Step S113.

When it is determined that the plasma state in the plasma processing chamber 10 is the required state (S114: YES), the controller 2 purges the plasma processing chamber 10 to exhaust excessive components of the second gas (Step S116).

The controller 2 acquires sensing data output from the second sensor 108b during execution of ALD (actual experiment). The controller 2 measures/estimates a pattern shape of the workpiece on which the protective layer is formed by ALD based on the sensing data of the second sensor 108b (Step S117). The shape measured/estimated in Step S117 may be a shape of each of recesses formed on the surface of the workpiece or may be uniformity of an overall recess shape on the workpiece surface.

The controller 2 determines whether an ideal shape is obtained based on a measurement/estimation result of the pattern shape (Step S118). The controller 2 measures/estimates a shape of a protective layer formed by the ALD based on the sensor data obtained by the second sensor 108b, and determines whether the protective layer has a required thickness to determine whether an ideal shape is obtained. When an ideal shape is not obtained (S118: NO), the controller 2 returns the process to Step S110, and repeatedly executes the ALD.

The controller 2 may compare the measurement/estimation result of the pattern shape and a set value set for the pattern shape to each other, and may stop the following process according to a comparison result or output a warning.

The controller 2 may frequently acquire various types of output data output from the plasma processing apparatus 1 or various types of measurement data during execution of ALD, and may repeatedly execute the virtual ALD with reference to the acquired data. The controller 2 can derive the parameter to be applied to the actual experiment from the virtual ALD, and can apply the derived parameter to the ALD repeatedly executed in the plasma processing apparatus 1 (actual experiment).

The controller 2 executes virtual etching after executing the virtual ALD in Step S108 (Step S119). The controller 2 estimates a shape of the workpiece after the etching process by simulation when the pattern shape obtained by the virtual ALD in Step S108 is set as an initial shape. The controller 2 determines whether a required shape is obtained based on the result of the virtual etching, and when it is determined that a required shape is not obtained, the controller 2 returns the process to Step S104 or S108 and repeatedly executes the virtual experiment (the virtual etching and the virtual ALD).

The controller 2 acquires various parameters used in the virtual etching, and derives parameters to be applied to an actual experiment based on the acquired parameters (Step S120). The parameters derived from the virtual etching are the same as the parameters derived in Step S104. As in Step S104, the controller 2 can derive the parameters to be applied to the actual experiment by inputting the parameters acquired in Step S120 to a learning model of machine learning including deep learning or reinforcement learning, a statistical model, or a model including a combination thereof. The controller 2 may optimize the parameters to be applied to the actual experiment such that a concordance rate between the shape measured/estimated in the actual experiment and the shape predicted in the virtual experiment increases or the process processing time (throughput) is shortened.

The plasma processing apparatus 1 acquires the parameter derived by the virtual experiment of Step S119, and executes etching to which the acquired parameter is applied (Step S121). The etching process is a process in the actual experiment.

The controller 2 acquires sensing data output from the second sensor 108b during execution of etching (actual experiment). The controller 2 measures/estimates a pattern shape of a pattern formed by the etching in Step S121 based on the sensing data of the second sensor 108b (Step S122). The shape measured/estimated in Step S122 may be a shape of each of recesses formed on the surface of the workpiece or may be uniformity of an overall recess shape on the workpiece surface.

The controller 2 determines whether an ideal shape is obtained based on a measurement/estimation result of the pattern shape (Step S123). A determination method of Step S123 is the same as the determination method of Step S107.

When it is determined that an ideal shape is not obtained (S123: NO), the controller 2 returns the process to Step S105. When it is determined that an ideal shape is obtained (S123: YES), the controller 2 ends the process of the present flowchart.

The controller 2 may compare the measurement/estimation result of the pattern shape and a set value set for the pattern shape to each other, and may stop the following process according to a comparison result or output a warning.

The flowcharts of FIGS. 6 and 7 illustrate a configuration where one plasma processing apparatus 1 executes the etching and the ALD. However, a plurality of process modules PM1 to PM6 may be configured to execute the etching and the ALD. When one plasma processing apparatus 1 executes the etching and the ALD, the controller 2 may measure/estimate a pattern shape or a plasma state based on the output of the optical sensor 108 provided in the plasma processing apparatus 1 (in-situ). When the plurality of process modules PMI to PM6 are used, for example, the pattern shape may be measured/estimated using the observation apparatus OC (ex-situ), and the plasma state may be measured/estimated using the first sensor 108 a provided in each of the process modules PM1 to PM6.

In addition, the flowcharts of FIGS. 6 and 7 illustrate the configuration where the controller 2 executes the virtual etching and the virtual ALD. Alternatively, necessary information may be delivered between the controller 2 and the control apparatus MC, and the control apparatus MC may be configured to execute the virtual etching and the virtual ALD.

Hereinafter, a configuration example of a simulator used in the virtual etching and the virtual ALD will be described.

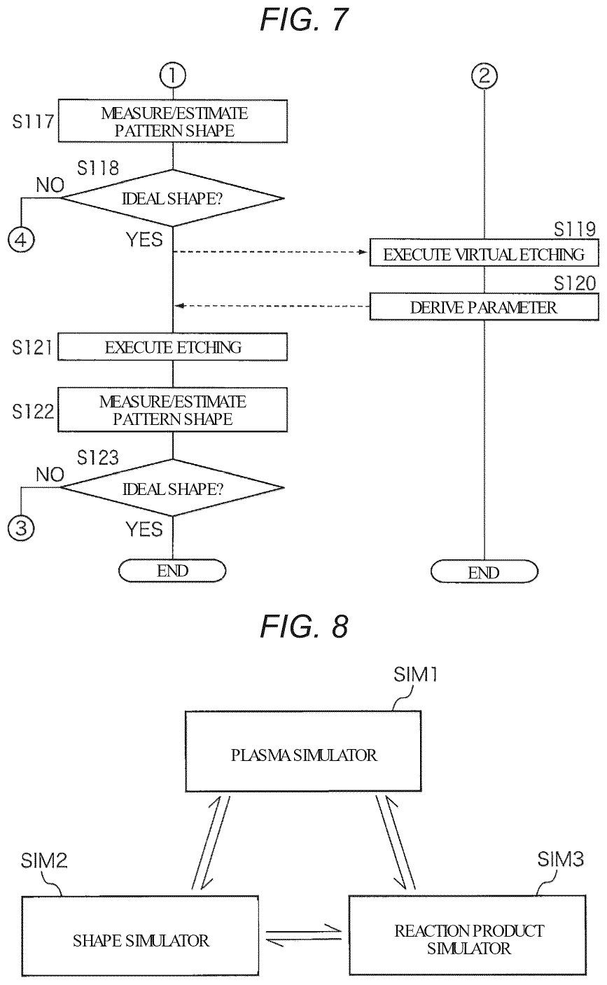

FIG. 8 is a diagram illustrating a configuration example of the etching simulator. The etching simulator is configured with, for example, a plasma simulator SIM1, a shape simulator SIM2, and a reaction product simulator SIM3. The simulators SIM1 to SIM3 are simulators using a particle model.

Based on process condition information, the plasma simulator SIM1 acquires a spatial distribution of reactive species (for example, ions or radicals) in the plasma processing chamber 10, and further acquires incidence information such as an incidence angle or incidence energy of the reactive species. Here, the process condition information is a type of reactive gas, a gas flow rate, a gas mixing ratio, a gas pressure, source RF power, bias RF power, and the like.

For example, the plasma simulator SIM1 acquires an electric field distribution from Poisson's equation, calculates a spatial distribution of reactive species using Particle Monte Carlo method, samples movement of reactive species in the vicinity of the workpiece, and acquires incidence information such as an incidence angle or incidence energy of the reactive species on the workpiece. Here, in the Particle Monte Carlo method, charged particles in plasma are represented by supraparticles, and trajectories of several thousands to several hundreds of thousands of supraparticles are tracked to simulate behavior of all plasma.

The shape simulator SIM2 acquires a local etching reaction amount and a macro etching reaction amount using not only the distribution amount and the incidence information of the reactive species acquired by the plasma simulator SIM1 but also information regarding a pattern shape of the workpiece surface. The plasma simulator SIM1 appropriately updates the distribution amount and the incidence information of the reactive species using the local etching reaction amount and the macro etching reaction amount acquired by the shape simulator SIM2.

The reaction product simulator SIM3 acquires a local adhesion amount of the reaction product, acquires a macro adhesion amount of the reaction product, and acquires a total adhesion amount of the reaction product using not only the distribution amount and the incidence information of the reactive species acquired by the plasma simulator SIM1 but also the local etching reaction amount and the macro etching reaction amount acquired by the shape simulator SIM2.

The shape simulator SIM2 divides a space partitioned by the pattern shape in a mesh shape, and flies the reactive species and the product species according to the Particle Monte Carlo method to the space to satisfy the incidence angle obtained from the plasma simulator SIM1. When the particles collide with a wall surface of a mask or the like, particles are set to react at a certain probability. When the amount of the reactive species in the mesh is a certain value or more, a material of the mesh portion is removed to deal with a phenomenon in which the portion disappears due to the progress of etching. When the amount of the product species is a certain value or more, a material corresponding to the product species (for example, a polymer) adheres to the wall surface to deal with a deposition reaction. The controller 2 acquires an etching shape of the workpiece by executing repeat calculation using such an etching simulator.

FIG. 8 illustrates the configuration example of the etching simulator, which is the same as the configuration example of the ALD simulator. That is, the ALD simulator is configured with, for example, a plasma simulator, a shape simulator, and a reaction product simulator. The plasma simulator calculates the distribution amount and the incidence information of the reactive species, the shape simulator calculates local and macro deposition reaction amounts, and the reaction product simulator calculates local and macro adhesion amounts of the reaction product. The controller 2 may acquire the shape of the protective layer formed on the sidewall of the recess using the ALD simulator configured as such.

Referring to FIG. 8, the etching simulator configured with the plasma simulator SIM1, the shape simulator SIM2, and the reaction product simulator SIM3 has been described. However, the configuration of the simulator is not limited to that illustrated in FIG. 8. The controller 2 can calculate the etching shape or the shape of the protective layer using any simulator (model) that can virtually describe the process.

In the substrate processing system PS according to the present embodiment, the actual experiment and the virtual experiment are executed simultaneously. When the result of the actual experiment and the result of the virtual experiment are obtained, the controller 2 may update the simulator (model) used in the virtual experiment to conform to the result of the actual experiment.

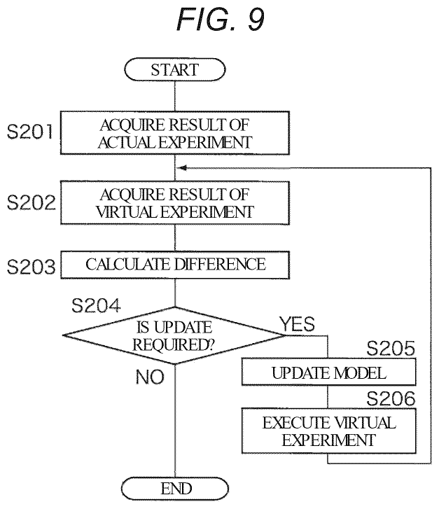

FIG. 9 is a flowchart illustrating a model update procedure. The controller 2 executes the actual experiment and the virtual experiment according to the procedure illustrated in FIGS. 6 and 7 to acquire the result of the actual experiment and the result of the virtual experiment (Steps S201 and S202).

The controller 2 calculates a difference between the result of the actual experiment and the result of the virtual experiment (Step S203), and determines whether update of the simulator (model) is necessary (Step S204). When the calculated difference is a set value or more, the controller 2 determines to update the simulator (model) (S204: YES), and updates the simulator (model) (Step S205). Specifically, the controller 2 changes at least one of the parameters configuring the simulator from a non-updated value to an updated value.

The controller 2 executes the virtual experiment including the virtual etching and the virtual ALD again using the updated simulator (model) (Step S206), and returns the process to Step S202. The controller 2 appropriately updates the model by repeating the process of Steps S202 to S206.

When the difference calculated in Step S203 is less than a threshold, the controller 2 determines that update is not necessary (S204: NO), and ends the process of the present flowchart.

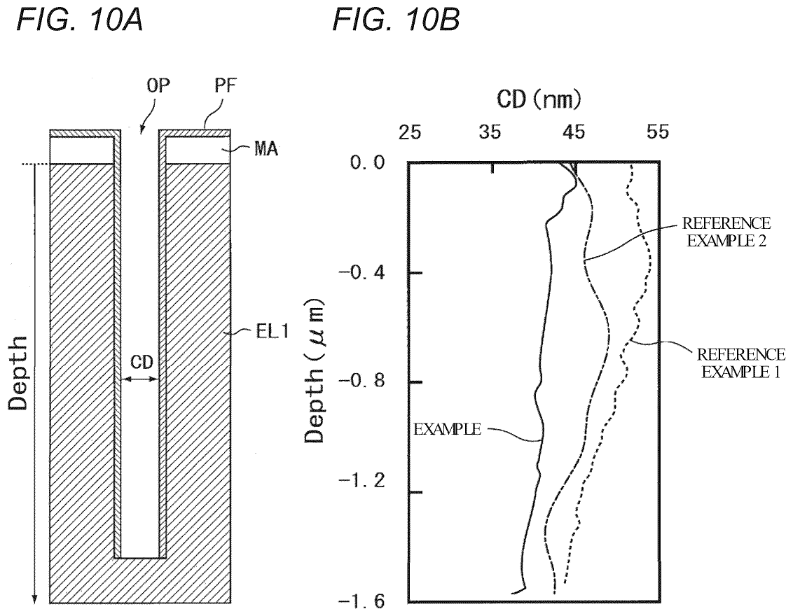

FIGS. 10A and 10B are diagrams illustrating a layer thickness of a protective layer formed using a substrate processing method according to the embodiment. FIG. 10A is a schematic diagram illustrating a workpiece used in an experiment. The workpiece includes an etching target layer EL1 and a mask MA. In a stacked body of the etching target layer EL1 and the mask MA, a recess including an opening OP is formed, and a protective layer PF is formed on a sidewall of the recess. In the present embodiment, an opening dimension CD at any position of a space surrounded by the sidewall of the recess (protective layer PF) was measured.

FIG. 10B is a graph illustrating measurement results. The vertical axis of the graph represents a depth of the recess, and the horizontal axis of the graph represents the opening dimension at any position of the space surrounded by the sidewall of the recess. Reference Example 1 represents an experiment result where only the etching process was executed and the ALD was not executed. Reference Example 2 represents an experiment result where both of the etching process and the ALD were executed. Meanwhile, Example represents an experiment result where the process condition was derived from the virtual etching and the virtual ALD using the substrate processing method according to the present embodiment and was applied to the actual experiment.

In Reference Example 1, the opening dimension CD decreased as the depth increased from a position having a depth of 0.4 μm. In the range illustrated in the graph, the maximum value of the opening dimension CD was 54.1 nm, and the minimum value of the opening dimension CD was 46.1 nm. Therefore, a difference between the maximum and minimum values was 8.0 nm.

In Reference Example 2, the opening dimension CD increased at a position having a depth in the range of 0.4 to 1.2 μm. In the range illustrated in the graph, the maximum value of the opening dimension CD was 49.2 nm, and the minimum value of the opening dimension CD was 42.2 nm. Therefore, a difference between the maximum and minimum values was 7.0 nm.

Meanwhile, in Example, it can be seen that the protective layer was formed with a substantially constant layer thickness regardless of the depth. In the range illustrated in the graph, the maximum value of the opening dimension CD was 45.6 nm, and the minimum value of the opening dimension CD was 40.0 nm. Therefore, a difference between the maximum and minimum values was 5.6 nm. That is, compared to Reference Example 1 or 2, Example was able to qualitatively show that a satisfactory opening shape was obtained.

As described above, in the present embodiment, the process condition derived from the virtual experiment (the virtual etching and the virtual ALD) is applied when executing the actual experiment. Therefore, a satisfactory opening shape can be guided. By updating the model based on the experiment result obtained in the actual experiment and the experiment result obtained in the virtual experiment, the number of trials in the actual experiment can be reduced, and a satisfactory opening shape can be guided more effectively.

### Second Embodiment

In a second exemplary embodiment, a configuration where a parameter to be applied to an actual experiment is derived using a method of reinforcement learning will be described.

Since an overall configuration of a substrate processing system and an apparatus configuration of each apparatus are the same as those of the first embodiment, the description thereof will not be repeated.

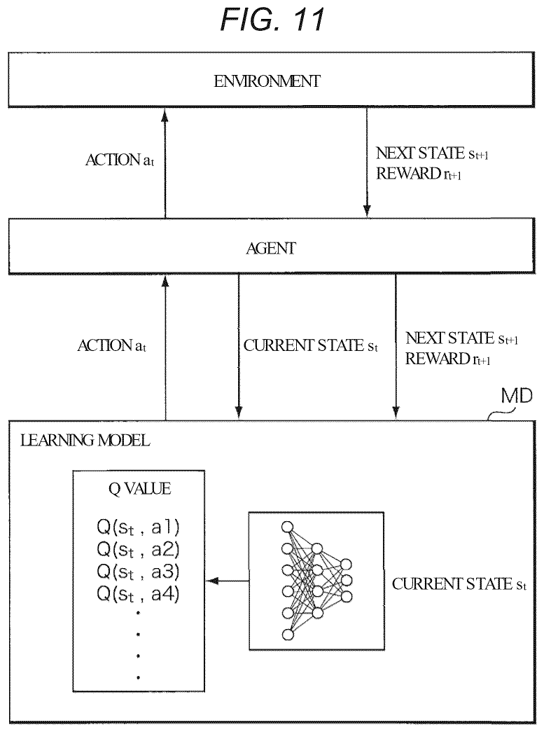

In the present embodiment, to derive the parameter to be applied to the actual experiment, a reinforcement learning algorithm is used. FIG. 11 is a schematic diagram illustrating the reinforcement learning algorithm. The reinforcement learning algorithm is an algorithm in which an agent in a certain environment observes a current state of an observation target to deal with a matter of determining an action to be taken. Hereinafter, Deep-Q Network (DQN) as a method of reinforcement learning will be described.

A learning model of reinforcement learning is learned such that, when a current state St of the observation target is input, a value of an action-value function (Q value) is output for each of actions a1, a2, . . . , and an (n represents an integer of 2 or more) that can be taken. A method of approximating the action-value function using a neural network to execute reinforcement learning is DQN.

In the present embodiment, a learning model MD is expressed using a neural network that approximates the action-value function, and reinforcement learning is executed such that information is output, in which the information is related to a value when a parameter to be applied to the actual experiment is selected according to the current state of the workpiece.

The state sₜ to be input to the learning model MD is, for example, data regarding a shape measured/estimated in the actual experiment. The learning model MD outputs values Q(sₜ,a1), Q(sₜ,a2), . . . , and Q(sₜ,an) of the action-value function with respect to the actions a1, a2, . . . , and an (n represents an integer of 2 or more) that can be taken in response to input of the current state sₜ, respectively. When an action a is selected in the state sₜ, the value of the action-value function represents an expected value of a profit that can be obtained in the future, and is also called the Q value. That is, the value of the action-value function (Q value) represent a long-term value instead of a short-term reward. In the present embodiment, the action a corresponds to execution of the actual experiment according to the selected parameter.

The agent refers to the Q value output for each action by the learning model MD and selects an action aₜ having the highest Q value among the actions a1, a2, . . . , and an that can be taken in the state sₜ. The environment is updated by the selected action aₜ to determine the next state sₜ₊₁. In the present embodiment, the agent is the controller 2, and the environment is a simulator that executes a virtual experiment.

The agent acquires a reward rₜ₊₁ from the environment according to the next state sₜ₊₁ generated by selecting the action aₜ. The reward rₜ₊₁ is, for example, a concordance rate between a shape of a recess measured/estimated by monitoring the actual experiment and a shape of a recess predicted by the virtual experiment. Alternatively, the reward rₜ₊₁ may be a process processing time.

The agent repeats trial and error, and learns an action such that the reward (profit) obtained in the future is maximized. Specifically, the agent sequentially updates the learning model MD based on the following expression (1) using the state sₜ, the state sₜ₊₁, and the reward rₜ₊₁ for the previous action aₜ.

Q(sₜ,aₜ)←Q(sₜ,aₜ)+α{rₜ₊₁+γ·maxQ(sₜ₊₁,aₜ₊₁)−Q(sₜ,aₜ)} (1)

Here, α represents a learning coefficient, γ represents a reduction rate, and rₜ₊₁ represents a reward obtained as a result of the action aₜ. The learning coefficient a is a parameter that determines a learning speed, and satisfies a relationship of 0<α<1. The reduction rate γ is a parameter representing a degree to which evaluation of the future state is reduced and evaluated, and satisfies a relationship of 0<γ<1.

In Q learning, a model parameter of the learning model MD is learned using error backpropagation or the like such that the second term on the right side of the expression (1) becomes zero. In other words, when the state sₜ transitions to the state sₜ₊₁ by the action aₜ, the Q value of the action aₜ approaches a value when the Q value in the next state s_{t +1} is the highest.

The agent repeats update of the learning model MD until a predetermined termination condition is satisfied. By repeating the update, the learning model MD learns such that the reward rₜ₊₁ is maximized. The termination condition is appropriately set to, for example, a condition that update was executed a predetermined number of times, a condition that the shape of the recess of the workpiece approached a target shape, or a condition that the workpiece cannot be cut anymore.

When the learning model MD is obtained by the above-described learning algorithm, the controller 2 can derive the parameter to be applied to the actual experiment using the learning model MD. Specifically, the controller 2 inputs the current state sₜ of the observation target (the data of the shape measured/estimated in the actual experiment) to the learned learning model MD, and executes the calculation using the learning model MD. As a result of the calculation using the learning model MD, the Q value is obtained for each of the actions a1, a2, . . . , and an that can be taken. By selecting an action having the highest Q value, the controller 2 can derive the parameter to be applied to the actual experiment.

As described above, in the second embodiment, the parameter to be applied to the actual experiment executed in the plasma processing apparatus 1 can be derived using the reinforcement learning. In the present embodiment, the configuration where the parameter to be applied to the actual experiment executed in one plasma processing apparatus 1 is derived has been described. However, of course, the parameter derived in one plasma processing apparatus 1 may be applied to other one or a plurality of plasma processing apparatuses.

In the present embodiment, for example, a learning algorithm using the Q learning has been described. However, the method of generating the learning model MD is not limited to the Q learning. For example, any reinforcement learning algorithm such as Temporal Difference learning (TD learning), Policy gradients, State-Action-Reward-State-Action (SARSA), and Actor-critic can be used.

### Third Embodiment

The first embodiment has the configuration where the controller 2 that controls the operation of the plasma processing apparatus 1 executes the virtual experiment and parameter derivation. Alternatively, an external server apparatus that is communicably connected to the controller 2 may execute the virtual experiment and the parameter derivation.

In a third exemplary embodiment, a configuration where the external server apparatus executes the virtual experiment and the parameter derivation will be described.

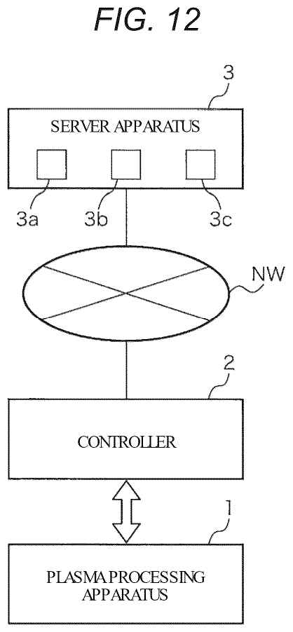

FIG. 12 is a schematic diagram illustrating a first configuration example of a plasma processing system according to the third embodiment. The plasma processing system according to the third embodiment includes the plasma processing apparatus 1, the controller 2, and a server apparatus 3. Since configurations of the plasma processing apparatus 1 and the controller 2 are the same as those of the first embodiment, the description thereof will not be repeated.

The server apparatus 3 is a computer that is communicably connected to the controller 2 via a communication network NW, and includes a processing unit 3a, a storage unit 3b, and a communication unit 3c. The processing unit 3a includes a CPU, a ROM, a RAM, and the like, executes a virtual experiment that simulates a process to be executed in the plasma processing apparatus 1 (actual experiment), and derives a parameter to be applied to the actual experiment. The storage unit 3b includes a storage apparatus such as an HDD or an SSD. The storage unit 3b includes a simulator for virtual experiment that simulates a process to be executed in the substrate processing system PS (actual experiment). The simulator for virtual experiment includes a plasma simulator, a reaction product simulator, and a shape simulator. The communication unit 3c includes a communication interface for communication with the controller 2 via the communication network NW.

The server apparatus 3 acquires data regarding a shape measured/estimated by the controller 2 during execution of the process (actual experiment) in the plasma processing apparatus 1 via the communication network NW. The server apparatus 3 sets the data regarding the shape acquired from the plasma processing apparatus 1 as an initial value, executes virtual etching or virtual ALD, and estimates a shape of a processed workpiece by simulation. The server apparatus 3 acquires various parameters used in the virtual etching or the virtual ALD, and derives parameters to be applied to the actual experiment based on the acquired parameters.

The server apparatus 3 may optimize the parameter to be applied to the actual experiment such that a concordance rate between the shape measured/estimated in the actual experiment and the shape predicted in the virtual experiment increases or the process processing time (throughput) is shortened. The server apparatus 3 may derive the parameter to be applied to the actual experiment using a method of reinforcement learning.

Since the above-described process executed by the server apparatus 3 is the same as the virtual experiment procedure described in the first and second embodiments, the detailed description thereof will not be repeated.

The server apparatus 3 transmits the derived parameter to the controller 2 via the communication network NW. The plasma processing apparatus 1 executes etching or ALD to which the parameter received from the server apparatus 3 by the controller 2 is applied. The etching or the ALD is a process in the actual experiment.

Since the above-described process executed by the plasma processing apparatus 1 is the same as the actual experiment procedure described in the first and second embodiments, the detailed description thereof will not be repeated.

As described above, in the third embodiment, the server apparatus 3 that is communicably connected to the controller 2 can execute the virtual experiment (the virtual etching or the virtual ALD), can derive the parameter to be applied to the plasma processing apparatus 1, and can feedback the parameter to the plasma processing apparatus 1.

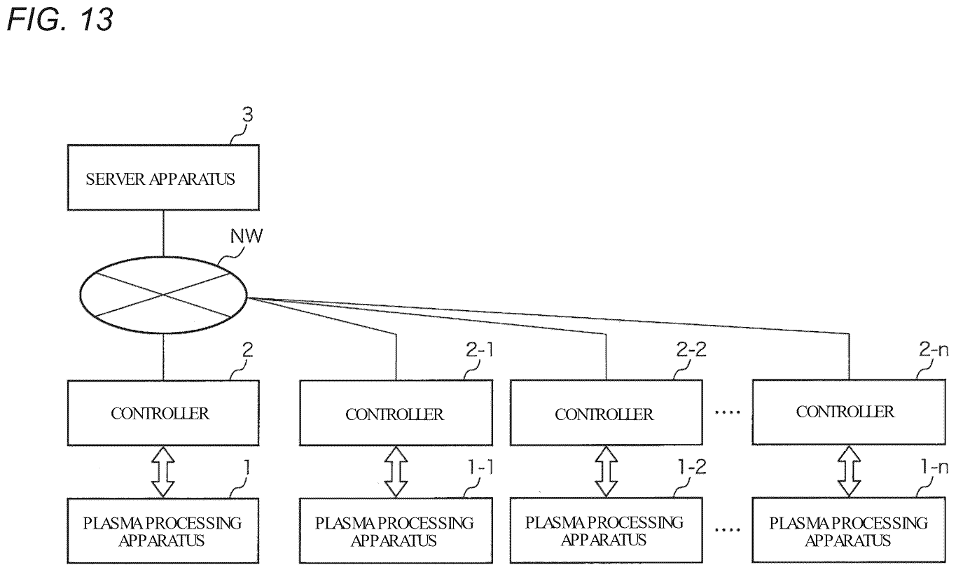

FIG. 13 is a schematic diagram illustrating a second configuration example of the plasma processing system according to the third embodiment. The plasma processing system according to the third embodiment includes not only the plasma processing apparatus 1, the controller 2, and the server apparatus 3 described above but also plasma processing apparatuses 1-1, 1-2, . . . , and 1-n and controllers 2-1, 2-2, . . . , and 2-n. The controllers 2-1, 2-2, . . . , and 2-n control operations of the plasma processing apparatuses 1-1, 1-2, . . . , and 1-n, respectively, and are connected to the plasma processing apparatuses 1-1, 1-2, . . . , and 1-n via the communication network NW, respectively.

As in the example of FIG. 12, the server apparatus 3 acquires the data obtained in the plasma processing apparatus 1, executes the virtual experiment (the virtual etching or the virtual ALD), and derives the parameter to be applied to the plasma processing apparatus 1. The server apparatus 3 transmits the derived parameter to the controller 2 that controls the plasma processing apparatus 1, and also transmits the derived parameter to the controllers 2-1, 2-2, . . . , and 2-n that control the plasma processing apparatuses 1-1, 1-2, . . . , and 1-n. The plasma processing apparatus 1 executes etching or ALD to which the parameter received from the server apparatus 3 by the controller 2 is applied. Likewise, the plasma processing apparatuses 1-1, 1-2, . . . , and 1-n execute etching or ALD to which the parameter received from the server apparatus 3 by the controllers 2-1, 2-2, . . . , and 2-n is applied.

As described above, in the second configuration example, the parameter to be applied to the plasma processing apparatus 1 can be derived, can be fed back to the plasma processing apparatus 1, and can also be fed back to the other plasma processing apparatuses 1-1, 1-2, . . . , and 1-n.

The embodiments disclosed herein are merely examples in all aspects and should not be construed to limit the scope of the present invention. The scope of the present invention is defined by the claims, not by the above description, and all of changes having equivalent meaning and falling within the scope of the claims are intended to be included.

In the embodiments, application examples to a capacitively coupled plasma processing apparatus 1 have been described. However, the present invention is not limited to being applied to a capacitively coupled type, and is also applicable to a plasma processing apparatus of any type such as inductively coupled plasma (ICP), radial line slot antenna (RLSA), electron cyclotron resonance plasma (ECR), or helicon wave plasma (HWP). In addition, chemical vapor deposition (CVD) may also be used instead of ALD.

The present disclosure is not limited to only the above-described embodiments, which are merely exemplary. It will be appreciated by those skilled in the art that the disclosed systems and/or methods can be embodied in other specific forms without departing from the spirit of the disclosure or essential characteristics thereof. The presently disclosed embodiments are therefore considered to be illustrative and not restrictive. The disclosure is not exhaustive and should not be interpreted as limiting the claimed invention to the specific disclosed embodiments. In view of the present disclosure, one of skill in the art will understand that modifications and variations are possible in light of the above teachings or may be acquired from practicing of the disclosure.
Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.
No claim element herein is to be construed under the provisions of 35 U.S.C. 112 (f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.
The scope of the invention is indicated by the appended claims, rather than the foregoing description.

The present disclosure includes the following embodiments.

### Appendix 1

A control method of a substrate processing apparatus, the control method including:
a step a) of partially etching a workpiece to form a recess in the workpiece;
a step b) of forming a protective layer on a sidewall of the recess formed in the workpiece,
a step c) of further etching the workpiece where the recess and the protective layer are formed;
a step d) of repeating the steps b) and c);
a step e) of monitoring the workpiece obtained in at least one of the steps a) to d);
a step f) of executing a virtual experiment that simulates the steps a) to d);
a step g) of deriving a parameter to be applied to at least one of the steps a) to d) based on a monitoring result of the workpiece and a result of the virtual experiment; and
a step h) of executing at least one of the steps a) to d) to which the derived parameter is applied.

### Appendix 2

The control method of a substrate processing apparatus according to E1, the control method further including:
a step i) of updating a model for deriving the parameter based on a difference between a shape of the recess estimated by monitoring the workpiece and a shape of the recess predicted by the virtual experiment.

### Appendix 3

The control method of a substrate processing apparatus according to E1 or E2, in which
the step of forming the protective layer includes at least one selected from the group consisting of chemical vapor deposition (CVD), atomic layer deposition (ALD), and unsaturated ALD.

### Appendix 4

The control method of a substrate processing apparatus according to E1 or E2, in which
the step of forming the protective layer includes
a step of supplying gas including a precursor to the workpiece such that the precursor is adsorbed on at least the sidewall of the recess, and
a step of supplying reactive gas that reacts with the precursor to the workpiece to form the protective layer by reaction of the reactive gas and the precursor adsorbed on the recess.

### Appendix 5

The control method of a substrate processing apparatus according to any one of E1 to E4, in which
the parameter includes a layer formation condition of the protective layer.

### Appendix 6

The control method of a substrate processing apparatus according to E5, in which
the layer formation condition includes at least one of a layer formation method, a number of cycles, time, a gas species, a dilution rate, a temperature, and RF power.

### Appendix 7

The control method of a substrate processing apparatus according to any one of E1 to E6, in which
the parameter includes an etching condition for the workpiece.

### Appendix 8

The control method of a substrate processing apparatus according to E7, in which
the etching condition includes at least one of RF power, a processing time, a gas species, a mixing ratio of gas, and a temperature.

### Appendix 9

The control method of a substrate processing apparatus according to any one of E1 to E8, in which
the steps a) to d) or the steps a) to e) are executed in the same chamber.

### Appendix 10

The control method of a substrate processing apparatus according to any one of E1 to E8, in which
the steps a) to e) are executed in at least two or more chambers.

### Appendix 11

The control method of a substrate processing apparatus according to E1, the control method further including:
a step j) of stopping a process or outputting a warning according to a comparison result between a shape of the recess estimated by monitoring the workpiece and a set value set for the shape.

### Appendix 12

The control method of a substrate processing apparatus according to E1, the control method further including:
a step k) of generating a learning model that derives the parameter by reinforcement learning where a concordance rate between a shape of the recess estimated by monitoring the workpiece and a shape of the recess predicted by the virtual experiment or a process processing time is a reward; and
a step l) of applying the parameter derived using the learning model to a substrate process in one or a plurality of substrate processing apparatuses including the substrate processing apparatus.

### Appendix 13

A control method of a substrate processing apparatus,
the substrate processing apparatus being configured to execute a process including
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c), and
the control method including:
i) a step of acquiring a first piece of data representing a shape of the workpiece after the process of any of the steps a) to d);
a step ii) of executing a virtual experiment that simulates the steps a) to d) on the workpiece to acquire a second piece of data representing a shape of the workpiece after the virtual experiment; and
a step iii) of deriving a parameter to be applied to at least one of the steps a) to d) based on the first piece of data and the second piece of data.

### Appendix 14

A substrate processing system comprising:
a substrate processing apparatus that executes
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c); and
a control apparatus that includes
a monitoring unit configured to monitor the workpiece obtained in at least one of the steps a) to d),
a simulation unit configured to execute a virtual experiment that simulates the steps a) to d), and
a derivation unit configured to derive a parameter to be applied to at least one of the steps a) to d) based on a monitoring result of the workpiece and a result of the virtual experiment, in which the control apparatus causes the substrate processing apparatus to execute at least one of the steps a) to d) to which the derived parameter is applied.

### Appendix 15

The substrate processing system according to E14, in which
the control apparatus stops a process or outputs a warning according to a comparison result between a shape of the recess estimated by monitoring the workpiece and a set value set for the shape.

### Appendix 16

The substrate processing system according to E14, in which
the control apparatus
generates a learning model that derives the parameter by reinforcement learning where a concordance rate between a shape of the recess estimated by monitoring the workpiece and a shape of the recess predicted by the virtual experiment or a process processing time is a reward; and
applies the parameter derived using the learning model to a substrate process in one or a plurality of substrate processing apparatuses including the substrate processing apparatus.

### Appendix 17

A substrate processing system comprising:
a substrate processing apparatus being configured to execute a process including:
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c); and
a control apparatus being configured to execute a process including:
i) a step of acquiring a first piece of data representing a shape of the workpiece after the process of any of the steps a) to d);
a step ii) of executing a virtual experiment that simulates the steps a) to d) on the workpiece to acquire a second piece of data representing a shape of the workpiece after the virtual experiment; and
a step iii) of deriving a parameter to be applied to at least one of the steps a) to d) based on the first piece of data and the second piece of data.

1. A control method of a substrate processing apparatus, the control method comprising:
a step a) of partially etching a workpiece to form a recess in the workpiece;
a step b) of forming a protective layer on a sidewall of the recess formed in the workpiece;
a step c) of further etching the workpiece where the recess and the protective layer are formed;
a step d) of repeating the steps b) and c);
a step e) of monitoring the workpiece obtained in at least one of the steps a) to d);
a step f) of executing a virtual experiment that simulates the steps a) to d);
a step g) of deriving a parameter to be applied to at least one of the steps a) to d) based on a monitoring result of the workpiece and a result of the virtual experiment; and
a step h) of executing at least one of the steps a) to d) to which the derived parameter is applied.

2. The control method of a substrate processing apparatus according to claim 1, the control method further comprising:
a step i) of updating a model for deriving the parameter based on a difference between a shape of the recess estimated by monitoring the workpiece and a shape of the recess predicted by the virtual experiment.

3. The control method of a substrate processing apparatus according to claim 1, wherein
the step of forming the protective layer includes at least one selected from the group consisting of chemical vapor deposition (CVD), atomic layer deposition (ALD), and unsaturated ALD.

4. The control method of a substrate processing apparatus according to claim 1, wherein
the step of forming the protective layer includes
a step of supplying gas including a precursor to the workpiece such that the precursor is adsorbed on at least the sidewall of the recess, and
a step of supplying reactive gas that reacts with the precursor to the workpiece to form the protective layer by reaction of the reactive gas and the precursor adsorbed on the recess.

5. The control method of a substrate processing apparatus according to claim 1, wherein
the parameter includes a layer formation condition of the protective layer.

6. The control method of a substrate processing apparatus according to claim 5, wherein
the layer formation condition includes at least one of a layer formation method, a number of cycles, time, a gas species, a dilution rate, a temperature, and RF power.

7. The control method of a substrate processing apparatus according to claim 1, wherein
the parameter includes an etching condition for the workpiece.

8. The control method of a substrate processing apparatus according to claim 7, wherein
the etching condition includes at least one of RF power, a processing time, a gas species, a mixing ratio of gas, and a temperature.

9. The control method of a substrate processing apparatus according to claim 1, wherein
the steps a) to d) or the steps a) to e) are executed in the same chamber.

10. The control method of a substrate processing apparatus according to claim 1, wherein
the steps a) to e) are executed in at least two or more chambers.

11. The control method of a substrate processing apparatus according to claim 1, the control method further comprising:
a step j) of stopping a process or outputting a warning according to a comparison result between a shape of the recess estimated by monitoring the workpiece and a set value set for the shape.

12. The control method of a substrate processing apparatus according to claim 1, the control method further comprising:
a step k) of generating a learning model that derives the parameter by reinforcement learning where a concordance rate between a shape of the recess estimated by monitoring the workpiece and a shape of the recess predicted by the virtual experiment or a process processing time is a reward; and
a step l) of applying the parameter derived using the learning model to a substrate process in one or a plurality of substrate processing apparatuses including the substrate processing apparatus.

13. A control method of a substrate processing apparatus,
the substrate processing apparatus being configured to execute a process including
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c), and
the control method comprising:
a step i) of acquiring a first piece of data representing a shape of the workpiece after the process of any of the steps a) to d);
a step ii) of executing a virtual experiment that simulates the steps a) to d) on the workpiece to acquire a second piece of data representing a shape of the workpiece after the virtual experiment; and
a step iii) of deriving a parameter to be applied to at least one of the steps a) to d) based on the first piece of data and the second piece of data.

14. A substrate processing system comprising:
a substrate processing apparatus including circuitry configured to execute
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c); and
a control apparatus that includes
a monitor configured to monitor the workpiece obtained in at least one of the steps a) to d),
a simulator configured to execute a virtual experiment that simulates the steps a) to d), and
a deriver configured to derive a parameter to be applied to at least one of the steps a) to d) based on a monitoring result of the workpiece and a result of the virtual experiment, in which
the control apparatus causes the substrate processing apparatus to execute at least one of the steps a) to d) to which the derived parameter is applied.

15. The substrate processing system according to claim 14, wherein
the control apparatus is configured to stop a process or output a warning according to a comparison result between a shape of the recess estimated by monitoring the workpiece and a set value set for the shape.

16. The substrate processing system according to claim 14, wherein
the control apparatus is configured to
generate a learning model that derives the parameter by reinforcement learning where a concordance rate between a shape of the recess estimated by monitoring the workpiece and a shape of the recess predicted by the virtual experiment or a process processing time is a reward; and
apply the parameter derived using the learning model to a substrate process in one or a plurality of substrate processing apparatuses including the substrate processing apparatus.

17. A substrate processing system comprising:
a substrate processing apparatus being configured to execute a process including
a step a) of partially etching a workpiece to form a recess in the workpiece,
a step b) of forming a protective layer on a sidewall of the recess formed in the workpiece,
a step c) of further etching the workpiece where the recess and the protective layer are formed, and
a step d) of repeating the steps b) and c); and
a control apparatus being configured to execute a process including
i) a step of acquiring a first piece of data representing a shape of the workpiece after the process of any of the steps a) to d);
a step ii) of executing a virtual experiment that simulates the steps a) to d) on the workpiece to acquire a second piece of data representing a shape of the workpiece after the virtual experiment; and
a step iii) of deriving a parameter to be applied to at least one of the steps a) to d) based on the first piece of data and the second piece of data.

18. The control method of a substrate processing apparatus according to claim 2, wherein
the steps a) to d) or the steps a) to e) are executed in the same chamber.

19. The control method of a substrate processing apparatus according to claim 3, wherein
the steps a) to d) or the steps a) to e) are executed in the same chamber.

20. The control method of a substrate processing apparatus according to claim 2, wherein
the steps a) to e) are executed in at least two or more chambers.
